(19) United States
(12) Patent Application Publication
(10) Pub. No.: US 2021/0099140 A1
(43) Pub. Date: Apr. 1, 2021

(54) WIDE BANDWIDTH RADIO FREQUENCY (RF) AMPLIFIER

(71) Applicant: QUALCOMM INCORPORATED, San Diego, CA (US)

(72) Inventors: Muhammad HASSAN, San Diego, CA (US); Bhushan Shanti ASURI, San Diego, CA (US); Mahim RANJAN, San Diego, CA (US)

(21) Appl. No.: 16/589,175

(22) Filed: Oct. 1, 2019

(51) Int. Cl. H03F 3/193; H03F 3/45; H03F 1/32; H03F 1/56; H03H 11/32

(52) U.S. Cl. CPC H03F 3/193; H03F 3/45183; H03F 1/3205; H03F 1/565; H03F 2203/21139; H03F 2200/09; H03F 2200/318; H03F 2200/387; H03H 11/32

(57) ABSTRACT

An amplifier circuit includes an amplifier, a balun comprising a primary side having a primary inductance and a secondary side having a secondary inductance, the primary side coupled to an output of the amplifier, the secondary side coupled to a first output path of the amplifier circuit and a second output path of the amplifier circuit, a shunt inductance coupled to the first output path; and a compensating inductance in the balun, the compensating inductance coupled between a first node and a second node, the first node coupling the compensating inductance to the first output path, the second node coupling the secondary inductance to the compensating inductance.

### FIELD

The present disclosure relates generally to electronics, and more specifically to radio frequency amplifiers.

### BACKGROUND

In a radio frequency (RF) transceiver, a communication signal is typically amplified and transmitted by a transmit section. A transmit section may comprise one or more circuits that amplify and transmit the communication signal. The amplifier circuit or circuits may comprise one or more amplifier paths having one or more stages that may include one or more driver stages and/or one or more power amplifier stages. The amplifier circuit or circuits may generally be called upon to provide different levels of power amplification over a wide bandwidth, while attempting to provide both efficiency and linearity for a variety of different transmission signals. Often, the amplifier may be used to amplify one or more communication signals in more than one frequency band. Such systems may be referred to as “dual-band” or “multi-band,” where a single RF chain may be used to amplify and transmit signals in two or more different portions of the radio spectrum, which may or may not be continuous in frequency.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides an amplifier circuit having an amplifier, a balun comprising a primary side having a primary inductance and a secondary side having a secondary inductance, the primary side coupled to an output of the amplifier, the secondary side coupled to a first output path of the amplifier circuit and a second output path of the amplifier circuit, a shunt inductance coupled to the first output path; and a compensating inductance in the balun, the compensating inductance coupled between a first node and a second node, the first node coupling the compensating inductance to the first output path, the second node coupling the secondary inductance to the compensating inductance.

Another aspect of the disclosure provides a method for communication including selectively shifting an output frequency of an amplifier from a first output frequency to a second output frequency using a shunt inductor in a matching circuit coupled to the amplifier, and compensating for an output impedance mismatch caused by the shift in the output frequency of the amplifier from the first output frequency to the second output frequency using a portion of an inductance in a secondary side of a balun in the matching circuit.

Another aspect of the disclosure provides an amplifier circuit including an amplifier, a matching circuit comprising a multi-port device comprising a transformer having a primary side having a primary inductance and a secondary side having a secondary inductance, and a shunt inductance and a compensating inductance, the compensating inductance coupled between a first node located between the compensating inductance and the shunt inductance and a second node located between the compensating inductance and the secondary inductance.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2 is a block diagram showing a wireless device in which the exemplary techniques of the present disclosure may be implemented.

FIG. 3 is a schematic diagram illustrating an amplifier circuit.

FIG. 4 is a schematic diagram illustrating an amplifier circuit in accordance with an exemplary embodiment of the disclosure.

FIG. 5 is a graph showing exemplary amplifier response between approximately 3.4 GHz and 6 GHz.

FIG. 6 is a flow chart describing the operation of an exemplary embodiment of an amplifier circuit in accordance with an exemplary embodiment of the disclosure.

FIG. 7 is a functional block diagram of an apparatus for an amplifier circuit in accordance with an exemplary embodiment of the disclosure.

### DETAILED DESCRIPTION

The word “exemplary” is used herein to mean “serving as an example, instance, or illustration.” Any aspect described herein as “exemplary” is not necessarily to be construed as preferred or advantageous over other aspects.

Exemplary embodiments of the disclosure are directed to a wide bandwidth, also referred to as dual-band, or multi-band, radio frequency (RF) amplifier that may be used to amplify communication signals in two or more frequency bands, which may or may not be continuous or contiguous in frequency. As used here, the terms “wide bandwidth” and “wideband” may refer to an RF amplifier that may operate over the above-mentioned two or more frequency bands, which may or may not be continuous or contiguous in frequency. In an exemplary embodiment, it may be desirable for a wide bandwidth RF amplifier to have the ability to amplify signals in both an ultra-high band (UHB) frequency range of approximately 3.4-3.8 GHz and an LTE assisted access (LAA) frequency range of approximately 5.1-6.00 GHz. It may also be desirable for a wide bandwidth RF amplifier to have the ability to amplify signals in WiFi frequency ranges of 2.4 GHz and 5 GHz. It may also be desirable for a wide bandwidth RF amplifier to have the ability to amplify multiple signals at other frequency ranges and at other frequency bands.

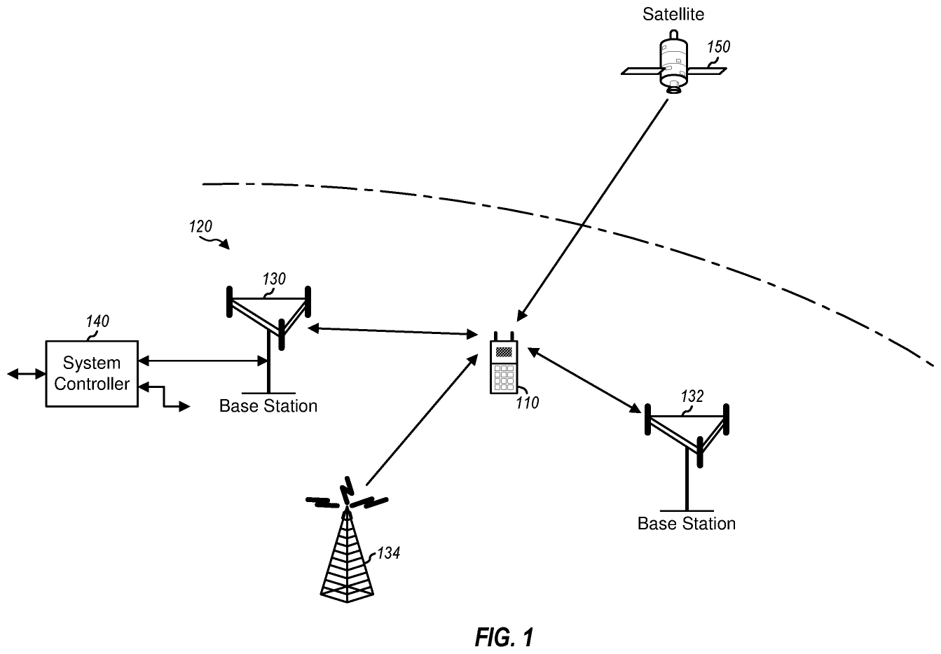

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G system, or some other wireless system. A CDMA system may implement Wideband CDMA (WCDMA), CDMA 1×, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134), signals from satellites (e.g., a satellite 150) in one or more global navigation satellite systems (GNSS), etc. Wireless device 110 may support one or more radio technologies for wireless communication such as LTE, WCDMA, CDMA 1×, EVDO, TD-SCDMA, GSM, 802.11, 5G, etc.

Wireless device 110 may support carrier aggregation, for example as defined in an LTE standard. Wireless device 110 may be able to operate in a variety of communication bands including, for example, those communication bands used by LTE, WiFi, 5G or other communication bands, over a wide range of frequencies. Other band configurations or configurations pursuant to a standard other than LTE or pursuant to an LTE release different than discussed herein may also used and/or implemented.

In general, carrier aggregation (CA) may be categorized into two types—intra-band CA and inter-band CA. Intra-band CA refers to operation on multiple carriers within the same band. Inter-band CA refers to operation on multiple carriers in different bands.

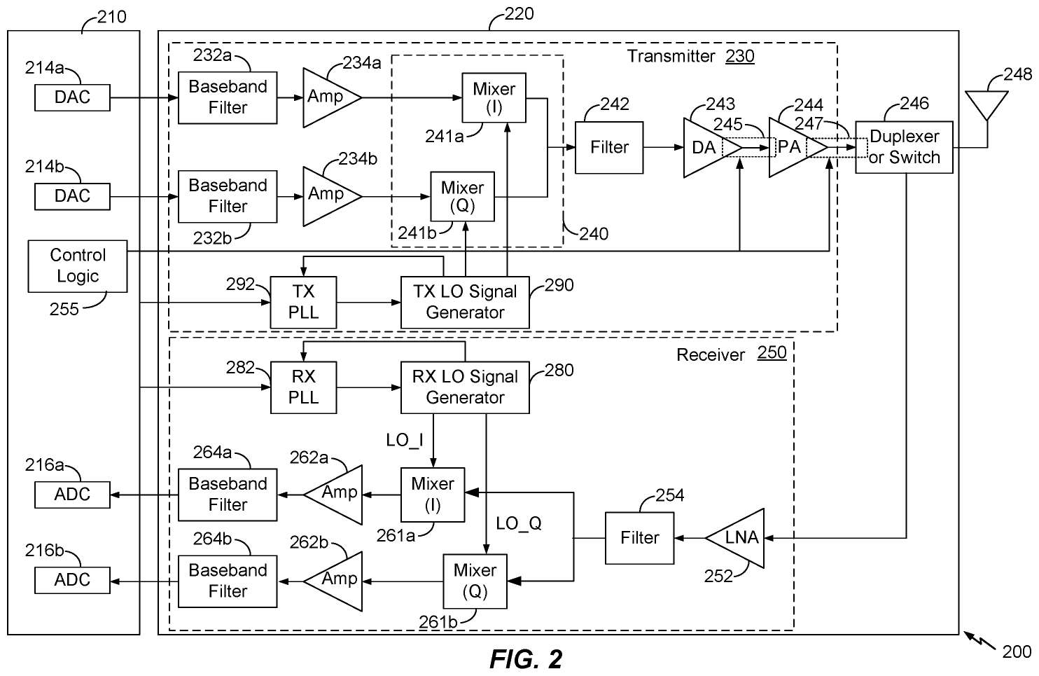

FIG. 2 is a block diagram showing a wireless device 200 in which the exemplary techniques of the present disclosure may be implemented. FIG. 2 shows an example of a transceiver 220. In general, the conditioning of the signals in a transmitter 230 and a receiver 250 may be performed by one or more stages of amplifier, filter, upconverter, downconverter, etc. These circuit blocks may be arranged differently from the configuration shown in FIG. 2. Furthermore, other circuit blocks not shown in FIG. 2 may also be used to condition the signals in the transmitter 230 and/or receiver 250. Unless otherwise noted, any signal in FIG. 2, or any other figure in the drawings, may be either single-ended or differential. Some circuit blocks in FIG. 2 may also be omitted.

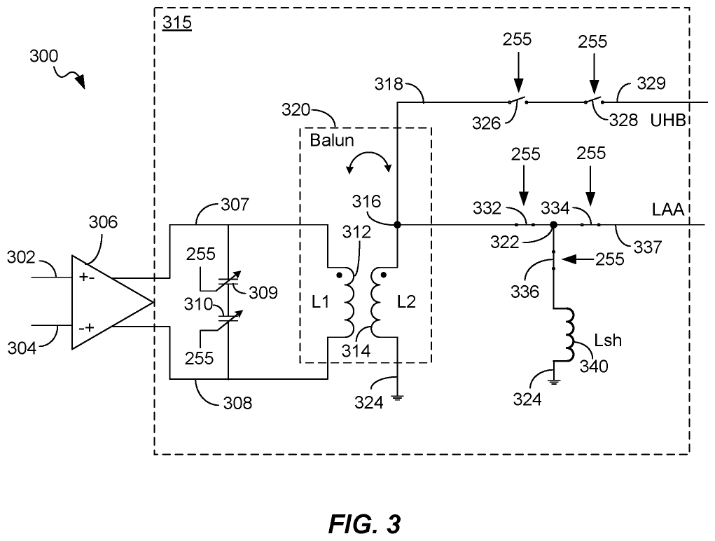

In the example shown in 2 FIG. 3, wireless device 200 generally comprises a transceiver 220 and a data processor 210. The data processor 210 may include a memory (not shown) to store data and program codes, and may generally comprise analog and digital processing elements. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., between RF and an intermediate frequency (IF) in one stage, and between IF and baseband in another stage. In the direct-conversion architecture, a signal is frequency converted between RF and baseband in one stage. The super-heterodyne and direct-conversion architectures may use different circuit blocks and/or have different requirements. In the example shown in FIG. 2, transmitter 230 and receiver 250 are implemented with the direct-conversion architecture. In other embodiments, the transmitter 230 and/or receiver 250 may be implemented with a super-heterodyne architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, lowpass filters 232a and 232b filter the I and Q analog transmit signals, respectively, to remove undesired images caused by the prior digital-to-analog conversion Amplifiers (Amp) 234a and 234b amplify the signals from lowpass filters 232a and 232b, respectively, and provide I and Q baseband signals. An upconverter 240 upconverts the I and Q baseband signals with I and Q transmit (TX) local oscillator (LO) signals from a TX LO signal generator 390 and provides an upconverted signal. A filter 242 filters the upconverted signal to remove undesired images caused by the frequency upconversion as well as noise in a receive frequency band. In an exemplary embodiment, a driver amplifier (DA) 243 amplifies the signal from filter 242 to an intermediate level, and a power amplifier (PA) 244 amplifies the signal from the driver amplifier 243 to obtain the desired output power level and provides a transmit RF signal. In other exemplary embodiments, the driver amplifier 243 may be omitted, or the PA 244 may be omitted from a particular transmit chain. The transmit RF signal is routed through a duplexer/filter or switch 246 and transmitted via an antenna 248. A matching network 245, which may be implemented as part of the driver amplifier 243, as part of the power amplifier 244, or as a stand-alone element, may provide interstage impedance matching between the output of the driver amplifier 243 and the input of the power amplifier 244. A matching network 247, which may be implemented as part of the power amplifier 244, as part of the duplexer/filter or switch 246, or as a stand-alone element, may provide output impedance matching between the output of the power amplifier 244 and the antenna 248.

The data processor 210 may also comprise a control logic 255 that may comprise hardware and/or software configured to control and/or adjust elements and components within the matching network 245 and/or the matching network 247.

In the receive path, antenna 248 receives communication signals and provides a received RF signal, which is routed through duplexer/filter or switch 246 and provided to a low noise amplifier (LNA) 252. The duplexer/filter or switch 246 is designed to operate with a specific RX-to-TX duplexer frequency separation, such that RX signals are isolated from TX signals. In a time division duplex (TDD) transmission system, the duplexer/filter or switch 246 may be implemented as a filter to isolate RX signals from TX signals. The received RF signal is amplified by LNA 252 and filtered by a filter 254 to obtain a desired RF input signal. Downconversion mixers 261a and 261b mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by lowpass filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280. While FIG. 2 illustrates I and Q signals, those of skill in the art will understand that the transceiver 220 may be implemented using a polar architecture.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain elements of the transceiver 220 are functionally illustrated in FIG. 2, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules. For example, any of the elements from the filter 242 to the duplexer/filter or switch 246 may be implemented in separate modules or as discrete components, while the remaining elements illustrated in the transceiver 220 may be implemented in a single transceiver chip.

The driver amplifier 243 and the power amplifier 244 may each comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver amplifier stages, one or more power amplifier stages, and/or one or more impedance matching networks, and can be configured to provide linearity, efficiency, or a combination of linearity and efficiency over a wide frequency range.

In an exemplary embodiment of the present disclosure, a multiple bandwidth, or wideband radio frequency (RF) amplifier may be incorporated with or into the driver amplifier 243 and/or the power amplifier 244 to provide wideband RF power amplification to signals over multiple frequency bands. In a particular exemplary embodiment, a wideband radio frequency (RF) power amplifier may be configured to provide one or more power amplification levels at one or more frequencies or over one or more frequency ranges. The frequency ranges may or may not be contiguous. Those of skill in the art, however, will recognize that aspects of the wideband radio frequency (RF) amplifier described herein may be implemented in transmit architectures which differ from the architecture illustrated in FIG. 2 and may be implemented in other devices in which RF amplification is desired. It is generally desirable for a radio frequency amplifier circuit to provide linear amplification over a desired bandwidth, which may be a wide bandwidth, support high data rate transmission, provide high efficiency over the desired power output range and bandwidth, and support multiple power modes. Aspects of the wideband radio frequency (RF) amplifier described herein may be implemented in a variety of amplifiers and amplifier circuits, including, for example, in the driver amplifier 243, the power amplifier 244, or other amplifiers or amplifier circuits.

Existing RF amplifier architectures can be configured for wide bandwidth operation by, for example, configuring a balun using various switches to enable operation at multiple bandwidths. A balun (a contraction of balanced-unbalanced) is a multiple port component placed between a source and load when a differential, balanced RF functional block connects to a single-ended, ground-referenced functional block, and can be part of an impedance matching network, such as the matching networks 245 and/or 247. For example, a balun may be used in the matching network 245 and/or the matching network 247 to convert a balanced, or differential, signal output of the driver amplifier 243 or the power amplifier 244 to a single ended, or unbalanced, output signal that may be provided to subsequent amplifier stages, to the duplexer/filter or switch 246, or to an antenna, such as the antenna 248.

A balun may be implemented using one or more inductive elements, such as inductors, and may be configured as a transformer. A balun may also provide impedance transformation, generally in systems where an unbalanced impedance of, for example 50 or 75 ohms, is coupled to a balanced impedance of, for example 200 or 300 ohms. Using an inductive balun to allow the RF amplifier to provide multiple band or high bandwidth operation generally causes degradation in the balun Q (the quality factor) and adds complexity and cost due to the additional switches used for the balun configuration.

In order to function at increased efficiency, a balun can be used with loads whose impedances present little or no reactance. Reactance is the non-resistive component of impedance in an AC circuit, arising from the effect of inductance or capacitance, or both, causing the current to be out of phase with the electromotive force (i.e., the voltage) causing it. Such impedances are referred to as “purely resistive.” As a general rule, a well-designed communications antenna presents purely resistive loads of 50, 75, or 300 ohms, although some antennas may have higher resistive impedances.

FIG. 3 is a schematic diagram conceptually illustrating an amplifier circuit. The amplifier circuit 300 conceptually illustrates the effect of impedance mismatch at the output of the amplifier circuit 300. In an exemplary embodiment, the amplifier circuit 300 may comprise a radio frequency (RF) amplifier 306 and a matching network 315.

In an exemplary embodiment, the radio frequency (RF) amplifier 306 has differential input terminals 302 and 304, over which an RF input signal may be provided. In this exemplary embodiment, the RF amplifier 306 is a differential amplifier, providing a differential amplified output on connections 307 and 308. Adjustable capacitors 309 and 310 are located across the differential outputs on connections 307 and 308. The capacitors 309 and 310 may be controlled by signals from the control logic 255 in the data processor 210 (FIG. 2).

A balun 320 is located at the output of the RF amplifier 306. In an exemplary embodiment, the balun 320 comprises an electromagnetic coupling having a primary portion L1 (or winding) 312 and a secondary portion L2 (or winding) 314. The primary portion 312 is coupled to the differential outputs of the RF amplifier 306 on connections 307 and 308. The capacitors 309 and 310 resonate with the primary portion (or winding) 312 of the balun 320 based on a desired tuning frequency, which can be adjusted using, for example, a digital code controlled by software and which may be determined by the control logic 255 according to the desired tuning frequency and used to control the capacitance of the capacitors 309 and 310 to adjust the tuning frequency. The secondary portion 314 of the balun 320 is coupled to a node, or tap, 316 and connection 318 on one side, and is coupled to, or referenced to, a system ground reference on connection 324 on the other side.

In an exemplary embodiment, an output of the amplifier circuit 300 may be taken from node 316 and over connection 318, through switches 326 and 328, and over connection 329 when the switches 326 and 328 are made conductive by a control signal generated by, for example, the control logic 255 in the data processor 210 (FIG. 2). In such configuration (not illustrated) in which the switches 326 and 328 are made conductive, a signal at a UHB output frequency may be provided over connection 329 to the duplexer/filter or switch 246 (FIG. 2). Further, in such configuration, switches 332, 334, and 336 may be controlled to be non-conductive. The switches 326, 328, 332, 334, and 336 may be selectively controlled to be conductive or non-conductive by signals generated by, for example, the control logic 255 in the data processor 210 (FIG. 2) or another control element.

In an exemplary embodiment, another output of the amplifier circuit 300 may be selectively taken from node 316, over connection 322, through switches 332 and 334, and over connection 337 when the switches 332 and 334 are made conductive by a control signal generated by, for example, the control logic 255 in the data processor 210 (FIG. 2). In such configuration, illustrated in FIG. 3, in which the switches 332 and 334 are made conductive, a signal at an LAA output frequency may be provided over connection 337 to the duplexer/filter or switch 246 (FIG. 2). Further, in such configuration, the switch 336 may be controlled to be conductive, and the switches 326 and 328 may be controlled to be non-conductive. The switches 326, 328, 332, 334, and 336 may be selectively controlled to be conductive or non-conductive by signals generated by, for example, the control logic 255 in the data processor 210 (FIG. 2) or another control element. Although shown as having outputs at UHB and LAA frequencies, the amplifier circuit 300 may have outputs at other frequencies, such as, for example, one or more outputs at WiFi frequencies at, for example, 2.4 GHz and 5 GHz.

The use of two switches at the output of the matching circuit 315, such as the switches 326 and 328 at the UHB output on connection 329, and the switches 332 and 334 at the LAA output on connection 337, may provide high port-to-port isolation. For example, it may be desirable to have high isolation between the UHB output port on connection 329 and the LAA output port on connection 337. For example, if the UHB output on connection 329 is ON, it may be desirable to prevent signal leakage to the LAA output and vice versa. In some embodiments, one of the switches 326 and 328 is omitted, and/or one of the switches 332, 334, and 336 is omitted.

An inductive element 340, may be coupled between the connection 322 and the ground reference 324 through the switch 336. The inductive element 340 may be referred to as a shunt inductor, Lsh, and may be switched into and out of the output connection 337 using the switch 336, which can be made conductive or non-conductive by a control signal generated by, for example, the control logic 255 in the data processor 210 (FIG. 2), or another element.

When the switches 332 and 334 are made conductive to couple the node 316 to the connection 337, coupling the inductive element 340 between the connection 322 and the ground reference 324 by making the switch 336 conductive desirably shifts the resonant frequency of the balun 320, but may also increase the output impedance mismatch between the RF amplifier 306 and the output connection 337, and thus decrease amplifier linearity and degrade the adjacent channel leakage ratio (ACLR) of the amplifier circuit 300. Coupling the inductive element 340 in parallel with the secondary portion 314 lowers the inductance of the balun 320, and allows tuning the output of the RF amplifier 306 to a higher frequency than when the switch 336 is non-conductive.

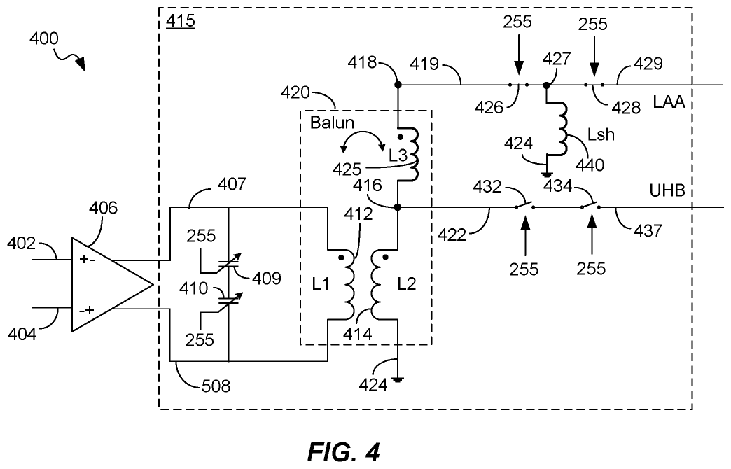

FIG. 4 is a schematic diagram illustrating an amplifier circuit 400 in accordance with an exemplary embodiment of the disclosure. In an exemplary embodiment, the amplifier circuit 400 may comprise a radio frequency (RF) amplifier 406 and a matching network 415. The matching network 415 may be an example of the matching network 247 of FIG. 2. However, the matching network 415 may also be an example of the matching network 245 of FIG. 2. In an exemplary embodiment, the amplifier circuit 400 illustrates an implementation of a wideband radio frequency (RF) amplifier with output impedance matching at multiple output frequencies.

In an exemplary embodiment, the radio frequency (RF) amplifier 406 has differential input terminals 402 and 404, over which an RF input signal may be provided. In this exemplary embodiment, the power amplifier 406 is a differential amplifier, providing a differential amplified output on connections 407 and 408. Adjustable capacitors 409 and 410 are located across the differential outputs on connections 407 and 408. The adjustable capacitors 409 and 410 may be controlled by signals from the control logic 255 in the data processor 210 (FIG. 2).

A balun 420 is located at the output of the RF amplifier 406. In an exemplary embodiment, the balun 420 comprises an electromagnetic coupling having a primary portion L1 (or primary inductance, or primary winding) 412 and a secondary portion L2 (or secondary inductance, or secondary winding) 414. The primary portion 412 is coupled to the differential outputs of the RF amplifier 406 on connections 407 and 408. The secondary portion 414 is coupled to a node, or tap, 416 and is coupled to, or referenced to, a system ground reference on connection 424. In this exemplary embodiment, the balun 420 also comprises an additional secondary portion L3 425 (or additional secondary inductance, or additional secondary winding) coupled between the node, or tap 416, and a node 418. In an exemplary embodiment, the additional secondary portion L3 425 may also be referred to as a compensating inductance. In some embodiments, the secondary portion L2 414 and the additional secondary portion L3 425 are implemented as portions of a single coil or winding with a tap 416 therebetween. In some embodiments, the secondary portion L2 414 and the additional secondary portion L3 425 are implemented as separate coils, windings, discrete inductors, or other structures providing inductance.

In an exemplary embodiment, an output of the amplifier circuit 400 may be taken over connection 419, through switches 426 and 428, and over connection 429 when the switches 426 and 428 are made conductive by a control signal generated by, for example, the control logic 255 in the data processor 210 (FIG. 2). In such configuration, illustrated in FIG. 4, in which the switches 426 and 428 are made conductive, a signal at an LAA output frequency may be provided over connection 429. Further, in such configuration, switches 432 and 434 may be controlled to be non-conductive. The switches 426, 428, 432, and 434 may be controlled by signals generated by, for example, the control logic 255 in the data processor 210 (FIG. 2) or another control element.

In accordance with an exemplary embodiment, an inductive element 440 may be coupled between the connection 427 and the ground reference 424. In an exemplary embodiment, the inductive element 440 may be implemented using a separate, discrete inductor or inductive element, for example in contrast with using the inductance in a circuit trace or the inductance of one or more of the switches 426 and 428. In an exemplary embodiment, the inductive element 440 may be implemented using an inductor, such as, for example, a surface mount device (SMD), and may be located on the die, laminate, or other structure on which the amplifier circuit 400 may be located. The inductive element 440 may be referred to as a shunt inductor, Lsh, and may be switched into and out of the output connection 429 by selectively enabling the switches 426 and 428. In an exemplary embodiment, when the switches 426 and 428 are conductive, the inductive element 440 is coupled to the node 418 and the connection 429.

In an exemplary embodiment, the value of the inductances L1 412, L2 414, L3 425, and Lsh 440 may be related as follows:

L1/(L2+L3)=1.4;

L3/L2=0.3;

Lsh/L2=0.8.

Those of skill in the art will appreciate that other values or ratios of inductors may be used.

In an exemplary embodiment, another output of the amplifier circuit 400 may be taken from node 416, over connection 422, through switches 432 and 434, and over connection 437 when the switches 432 and 434 are made conductive by a control signal generated by, for example, the control logic 255 in the data processor 210 (FIG. 2). In such configuration (not illustrated) in which the switches 432 and 434 are conductive, a signal at a UHB output frequency may be provided over connection 437. Further, in such configuration, the switches 426 and 428 may be controlled to be non-conductive. The switches 426, 428, 432, and 434 may be selectively controlled by signals generated by, for example, the control logic 255 in the data processor 210 (FIG. 2) or another control element to selectively couple the node 416 to the output on connection 437. In some embodiments, one of the switches 432 and 434 is omitted.

As mentioned above with regard to FIG. 3, coupling the inductive element 440 between the connection 427 and the ground reference 424 may shift (in this example, increase) the resonant frequency of the balun 420, but also increase the output impedance mismatch between the RF amplifier 406 and the output connection 429, thus decreasing amplifier linearity and degrading the adjacent channel leakage ratio (ACLR) of the amplifier circuit 400.

Advantageously, the balun ratio of the balun 420 can be lowered by the additional secondary portion L3 425 located between the node 416 and the node 418. Thus, any decrease in amplifier linearity and/or degradation of adjacent channel leakage ratio (ACLR) of the amplifier circuit 400 (e.g., due to increased output impedance mismatch) which might otherwise be introduced by coupling the inductive element 440 between the connection 427 and the ground reference 424 to shift the resonant frequency of the balun 420 can be reduced or eliminated.

In an exemplary embodiment, the impedance appearing at nodes 416 and 418 will be transformed by the impedance transformation ratio of the balun 420 and may appear as an impedance mismatch at the output of the RF amplifier 406. The impedance mismatch appearing at the node 418 will be higher than the impedance mismatch appearing at the node 416 because the inductive element 440 is coupled in parallel with the leakage inductance of the balun 420, thus increasing the impedance transformation ratio of the balun 420. Exemplary embodiments described herein; however, may reduce this impedance mismatch to alleviate the possibility that increased impedance mismatch at the node 418 will result in early compression of the RF amplifier 406 and hence degrade the linearity of the RF amplifier 406.

In an exemplary embodiment, the balun 420 has two impedance transformation ratios. The impedance transformation ratio at the node 418 is given by sqrt(L1/(L2+L3)). The impedance transformation ratio at the node 416 is given by sqrt(L1/L2). The node 418 exhibits a lower impedance transformation ratio than does the node 416 and thus allows higher output impedance at the node 418, which may be caused by the inductive element 440 being coupled between the connection 427 and the ground reference 424 (for example, to raise the tuning frequency), to be absorbed by the additional secondary portion L3 425. This may compensate for the increased impedance mismatch which might otherwise appear at the node 418. Stated differently, the lower impedance transformation ratio “sqrt (L1/(L2+L3))” at the node 418 may compensate for an increased impedance mismatch effect of the inductive element 440, which inductive element 440 can be used to shift the tuning frequency higher.

Without the inductive element 440, it is possible to adjust the output frequency, for example, from a lower frequency, f1 to a higher frequency, f2, by tuning, or adjusting the capacitance of the adjustable capacitors 409 and 410. However, by adding the inductive element 440, it is possible to tune to a higher frequency than when using the adjustable capacitors 409 and 410 alone to tune the output frequency of the amplifier circuit 400. For example, by adding the inductive element 440, it would be possible to adjust the output frequency to a frequency, f3, that is higher than the frequency, f2. In an exemplary embodiment, the inductive element 440 allows an extended tuning range that may be twice the range of using the adjustable capacitors 409 and 410 alone. In an exemplary embodiment, it is possible to design the amplifier circuit 400 so that its output frequency can be adjustable over a range of, for example, between 3.4 GHz and 4.2 GHz, and adjustable over a range of, for example, between 4.4 GHz to 6 GHz. Alternatively, it is possible to design the amplifier circuit 400 so that the output frequency may be continuously adjustable between, for example, 3.4 GHz to 6 GHz, depending on component selection.

For example, if the UHB output ranges from 3.4-3.8 GHz and the LAA output ranges from 5.1-6 GHz, then, in an exemplary embodiment, a frequency tuning range of 3.4-4.2 GHz may be implemented which covers a SUB6 5G band (e.g., channels 77/78) and a frequency tuning range of 4.4-6 GHz may be implemented which covers another 5G band (e.g., channel 79, covering 4.4-5 GHz) as well as covers LAA output ranges of 5.1-6 GHz. In this manner, one amplifier circuit may be used to cover the 77/78/UHB band and the 79/LAA band.

In an exemplary embodiment, the architecture of the amplifier circuit 400 may be configured to have the ability to amplify signals in other frequency ranges, such as for example, WiFi frequency ranges of 2.4 GHz and 5 GHz to provide dual band WiFi 2.4 GHz and WiFi 5 GHz outputs. In alternative exemplary embodiment, the amplifier circuit 400 may be configured to amplify multiple signals at other frequency ranges and at other frequency bands.

In an exemplary embodiment, a multi-tap balun secondary, for example as implemented by an additional secondary portion L3 425 creating the node 416 and the node 418, in combination with the inductive element 440 acting as a shunt inductor, allows the RF amplifier 406 to be tuned over a wide frequency range, while maintaining output impedance matching (load-line), ACLR, and Q factor.

In an exemplary embodiment, the output selection switches 426 and 428 are re-used for connecting and disconnecting both the inductive element 440 and the node 418 from the output 429, thus minimizing the number of switches used to couple the inductive element 440 to the output on connection 429. The inductive element 440 can be on the same die or on the same laminate as the other components in the matching circuit 415, or can be an external surface mount device (SMD).

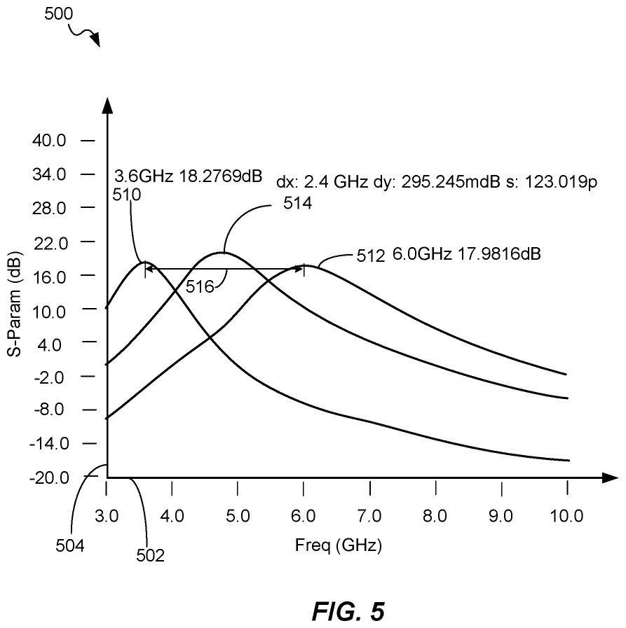

FIG. 5 is a graph 500 showing exemplary amplifier response between approximately 3.4 GHz and approximately 6 GHz. In an exemplary embodiment, the response traces shown in FIG. 5 illustrate the performance of an amplifier circuit as described herein for amplifying both a UHB communication signal and an LAA communication signal over the exemplary frequency range of 3.4-6 GHz.

The horizontal axis 502 shows frequency in GHz, and the vertical axis 504 shows exemplary amplifier scatter parameter (S-parameter), in dB. The trace 510 shows an S-parameter of approximately 18.2769 dB at approximately 3.6 GHz. The trace 512 shows an S-parameter of approximately 17.9816 dB at approximately 6.0 GHz. The trace 514 shows the S-parameter performance of an amplifier over an exemplary tuning range of approximately 3.4 GHz to approximately 6 GHz. The arrow 516 shows the approximate 2.4 GHz range of frequencies over which the amplifier represented by the trace 514 exhibits adequate performance over the 3.4 GHz to 6 GHz approximate tuning range and shows relatively constant gain across the exemplary tuning range of approximately 3.4 GHz to approximately 6.0 GHz.

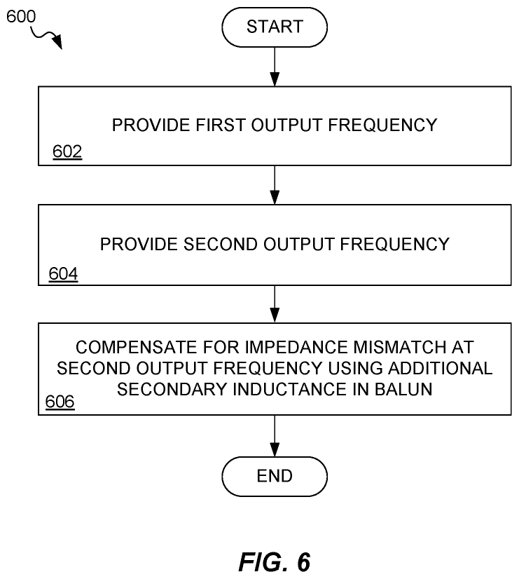

FIG. 6 is a flow chart 600 describing the operation of an exemplary embodiment of an amplifier in accordance with an exemplary embodiment of the disclosure. The blocks in the method 600 can be performed in or out of the order shown, and in some embodiments, can be performed at least in part in parallel.

In block 602, an output at a first frequency can be provided. For example, the amplifier circuit 400 can be configured to provide an output at a first frequency, which may be a frequency associated with a UHB communication signal. In an exemplary embodiment, the adjustable capacitors 409 and 410, the primary portion L1 412 and the secondary portion L2 414 can be chosen or configured to provide the first frequency output.

In block 604, an output at a second frequency can be provided. For example, the amplifier circuit 400 can be configured to provide an output at a second frequency, which may be a frequency associated with an LAA communication signal. In an exemplary embodiment, the second frequency may be higher than the first frequency. In an exemplary embodiment, the inductive element 440 can be chosen or configured to provide the second frequency output.

In block 606, impedance mismatch at the output of the amplifier circuit 400 at the second output frequency can be compensated using the additional secondary portion 425. In an exemplary embodiment, the additional secondary portion 425 can be chosen or configured to compensate for the impedance mismatch at the output of the amplifier circuit 400 at the second frequency caused by the inductive element 440, which provides the second frequency output.

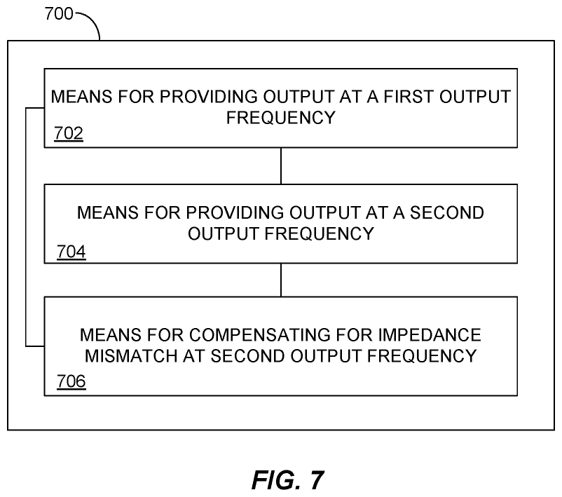

FIG. 7 is a functional block diagram of an apparatus 700 for an amplifier circuit in accordance with an exemplary embodiment of the disclosure. The apparatus 700 comprises means 702 for providing an output at a first output frequency. In certain embodiments, the means 702 for providing an output at a first output frequency can be configured to perform one or more of the functions described in operation block 602 of method 600 (FIG. 6). In an exemplary embodiment, the means 702 for providing an output at a first output frequency may comprise the amplifier circuit 400, for example including the capacitors 409 and 410 and/or the inductances L1 and L2, providing an output at a first output frequency.

The apparatus 700 further comprises means 704 for providing an output at a second output frequency. In certain embodiments, the means 704 for providing an output at a second output frequency can be configured to perform one or more of the functions described in operation block 604 of method 600 (FIG. 6). In an exemplary embodiment, the means 704 for providing an output at a second output frequency may comprise the amplifier circuit 400 having a shunt inductance selectively coupled to an output path for providing an output at a second output frequency.

The apparatus 700 further comprises means 706 for compensating for impedance mismatch at the second output frequency. In certain embodiments, the means 706 for compensating for impedance mismatch at the second output frequency can be configured to perform one or more of the functions described in operation block 606 of method 600 (FIG. 6). In an exemplary embodiment, the means 706 for compensating for impedance mismatch at the second output frequency may comprise the amplifier circuit 400 having a compensation inductance, for example coupled to or integrated with a secondary side of the balun 420, configured to compensate for impedance mismatch at the second output frequency.

The amplifier circuit described herein described herein may be implemented on one or more ICs, analog ICs, RFICs, mixed-signal ICs, ASICs, printed circuit boards (PCBs), electronic devices, etc. The amplifier circuit described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the amplifier circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC, (v) a module that may be embedded within other devices, (vi) a receiver, cellular phone, wireless device, handset, or mobile unit, (vii) etc.

In one or more exemplary designs, control for the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

As used in this description, the terms “component,” “database,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device may be a component. One or more components may reside within a process and/or thread of execution, and a component may be localized on one computer and/or distributed between two or more computers. In addition, these components may execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

Although selected aspects have been illustrated and described in detail, it will be understood that various substitutions and alterations may be made therein without departing from the spirit and scope of the present invention, as defined by the following claims.

What is claimed is:

1. An amplifier circuit, comprising:
an amplifier;
a balun comprising a primary side having a primary inductance and a secondary side having a secondary inductance, the primary side coupled to an output of the amplifier, the secondary side coupled to a first output path of the amplifier circuit and a second output path of the amplifier circuit;
a shunt inductance coupled to the first output path; and
a compensating inductance in the balun, the compensating inductance coupled between a first node and a second node, the first node coupling the compensating inductance to the first output path, the second node coupling the secondary inductance to the compensating inductance.

2. The amplifier circuit of claim 1, wherein the shunt inductance is configured to shift an output frequency of the amplifier circuit from a first output frequency to a second output frequency.

3. The amplifier circuit of claim 1, wherein the second node is coupled to the second output path.

4. The amplifier circuit of claim 3, wherein the first output path comprises a first switch configured to selectively conduct between the first node and the compensating inductance.

5. The amplifier circuit of claim 4, wherein the second output path comprises a second switch in series in the second output path, and wherein the secondary inductance is coupled between the second node and ground.

6. The amplifier circuit of claim 1, wherein the amplifier comprises differential outputs coupled to the first inductance, and wherein the amplifier circuit further comprises one or more adjustable capacitors coupled between the differential outputs.

7. A method for communication, comprising:
selectively shifting an output frequency of an amplifier from a first output frequency to a second output frequency using a shunt inductor in a matching circuit coupled to the amplifier; and
compensating for an output impedance mismatch caused by the shift in the output frequency of the amplifier from the first output frequency to the second output frequency using a portion of an inductance in a secondary side of a balun in the matching circuit.

8. The method of claim 7, wherein the compensating further comprises:
maintaining an output impedance match at the second output frequency.

9. The method of claim 7, further comprising:
generating an impedance transformation ratio at the second output frequency that is lower than an impedance transformation ratio at the first output frequency.

10. The method of claim 7, further comprising:
selecting the first output frequency from a first range of output frequencies; and
selecting the second output frequency from a second range of output frequencies.

11. The method of claim 7, further comprising selecting the first output frequency and the second output frequency from a single range of output frequencies.

12. An amplifier circuit, comprising:
an amplifier;
a matching circuit comprising a multi-port device comprising a transformer having a primary side having a primary inductance and a secondary side having a secondary inductance; and
a shunt inductance and a compensating inductance, the compensating inductance coupled between a first node located between the compensating inductance and the shunt inductance and a second node located between the compensating inductance and the secondary inductance.

13. The amplifier circuit of claim 12, wherein the multi-port device is configured to convert a balanced output of the amplifier to a single-ended output signal.

14. The amplifier circuit of claim 13, wherein the shunt inductance is configured to shift an output frequency of the single-ended output signal from a first output frequency to a second output frequency.

15. The amplifier circuit of claim 14, wherein the compensating inductance is configured to maintain an output impedance match at an output of the amplifier when an output of the amplifier circuit is provided from the shunt inductance at the second output frequency.

16. The amplifier circuit of claim 14, wherein the compensating inductance is configured to generate an impedance transformation ratio at the second node that is lower than an impedance transformation ratio at the first node.

17. The amplifier circuit of claim 14, wherein the first output frequency is selected from a first range of output frequencies and the second output frequency is selected from a second range of output frequencies.

18. The amplifier circuit of claim 14, wherein the first output frequency and the second output frequency are selected from a single range of output frequencies.

19. The amplifier circuit of claim 12, wherein the secondary inductance and the compensating inductance comprise a single winding and the second node comprises a tap on the single winding.

20. The amplifier circuit of claim 12, wherein the first node is coupled to an output for an LTE assisted access (LAA) frequency and the second node is coupled to an output for an ultra-high band (UHB) frequency.
